(19) United States
(12) Patent Application Publication
(10) Pub. No.: US 2026/0371805 A1
(43) Pub. Date: Nov. 19, 2026

(54) METAL GRATING FOR LOSSLESS CURRENT SPREADING AND MANUFACTURING METHOD THEREOF AND LED CHIP

(71) Applicant: GOLDEN SCORPION (AH) CO., LTD., Maanshan (CN)

(72) Inventors: Shengmao MA, Maanshan (CN); Shilong FENG, Maanshan (CN); Lingsong E, Maanshan (CN); Runzhang HONG, Maanshan City (CN); Jian GUO, Maanshan (CN)

(21) Appl. No.: 19/739,450

(22) Filed: Jul. 13, 2026

Related U.S. Application Data
(63) Continuation of application No. PCT/CN2026/087549, filed on Mar. 31, 2026.

(30) Foreign Application Priority Data
Mar. 24, 2026 (WO) PCT/CN2026/085512

(51) Int. Cl. H10H 20/857; H10H 20/01

(52) U.S. Cl. CPC H10H 20/857; H10H 20/0364

(57) ABSTRACT

The present invention provides a metal grating for lossless current spreading and a manufacturing method therefor, and an LED chip, which realizes efficient current spreading and reduces occlusion loss of emergent light. The metal grating is disposed at a light-emitting surface of the chip. An arrangement period of the metal grating is at a subwavelength scale of the emergent light of the chip. A width of the metal grating ranges from 1/9 to 1/7 of the arrangement period, and a thickness thereof ranges from 100-300% of a skin depth of a material of the metal grating.

### TECHNICAL FIELD

The present invention belongs to the field of LED chip manufacturing technologies, and in particular, to a metal grating for lossless current spreading and a manufacturing method, and an LED chip, especially an LED chip applicable for supplementary lighting for plants, which may also be widely applied to various LED chip manufacturing scenarios with high requirements on light efficiency.

### BACKGROUND

An LED chip is used as a core device in fields such as solid-state lighting, display, and supplementary lighting for plants. Light efficiency and current spreading uniformity of the LED chip directly determine overall performance of a device. In an operation process of the LED chip, a metal structure for current spreading is a key component for achieving an even distribution of current on a surface of the chip and lowering a volume resistivity of the chip, but the metal structure has core problems:
(1) A size of a conventional metal wire or metal grating for current spreading is usually greater than a wavelength of emergent light from the LED chip, seriously blocking light emitted from an epitaxial layer of the chip, causing a significant loss of the emergent light, and greatly reducing light efficiency of a chip.
(2) A current distribution among conventional metal wires is uneven, and the volume resistivity of the surface of the chip is relatively high, further affecting light emitting efficiency and operational stability of the LED chip.

Especially in the field of supplementary lighting for plants, the LED chip of a particular wavelength, such as red light, blue light, and infrared light, has an extremely high requirement on the light efficiency and a small increase in a light loss directly affects photosynthesis effects of plants and increases energy consumption for supplementary lighting. In the related art, to reduce a blocking rate of a metal grating, the width of the metal grating is usually reduced or a spacing between gratings is increased. However, this causes uneven current spreading and an increase in the volume resistivity of the chip, forming a conflict of “light efficiency-current spreading”. If the metal gratings are simply thickened to lower the resistivity, light blocking is further exacerbated, and performance of both cannot be balanced.

Therefore, development of a metal grating structure and a manufacturing method thereof that can not only achieve high-efficient current spreading but also reduce a blocking loss for emergent light to the greatest extent becomes a key to solve the bottleneck for the current technology.

### SUMMARY

With regard to the technical defects of the metal grating for current spreading of the LED chip in the related art, such as severe occlusion of emergent light, an uneven current distribution, and a high volume resistivity of a surface of the chip, the present invention provides a metal grating for lossless current spreading and a manufacturing method thereof, which achieves an extremely low rate at which the metal grating blocks light emitted from an epitaxial layer of the chip, thereby optimizing current spreading performance, and reducing a volume resistivity of a chip. The present invention is especially applicable to a chip for supplementary lighting for plants and may extend to various other types of LED chips, thereby improving overall light efficiency and operation stability of a chip.

The present invention adopts the following technical solutions:

A metal grating for lossless current spreading is provided, where the metal grating is disposed at a light-emitting surface of a chip;
an arrangement period of the metal grating is at a subwavelength scale of emergent light from the chip; and
a width of the metal grating ranges from 1/9 to 1/7 of the arrangement period, and a thickness of the metal grating ranges from 100-300% of a skin depth of a material of the metal grating. As shown in FIG. 1 or FIG. 2, the width of the metal grating is La, and the arrangement period is Lb, where La=( 1/9 to 1/7) Lb.

In the metal grating for lossless current spreading, the width of the metal grating is ⅛ of the arrangement period, and the thickness of the metal grating ranges from 150-250% of the skin depth of the material of the metal grating.

In the metal grating for lossless current spreading, the metal grating is higher than the light-emitting surface of the chip, and a wavelength of the emergent light is a wavelength of the emergent light in air.

In the metal grating for lossless current spreading, the metal grating is embedded in a light-emitting surface of the chip, a top of the metal grating is flush with the light-emitting surface of the chip, and the wavelength of the emergent light is an internal wavelength of the emergent light on the light-emitting surface of the chip.

In the metal grating for lossless current spreading, the emergent light of the chip is red light, the arrangement period of the metal grating is 400 nm±40 nm, the width of the metal grating is 50 nm±5 nm, and the thickness of the metal grating is 60 nm±6 nm.

In the metal grating for lossless current spreading, the emergent light of the chip is red light, the arrangement period of the metal grating is 160 nm±15 nm, the width of the metal grating is 20 nm±3 nm, and the thickness of the metal grating is 25 nm±3 nm.

In the metal grating for lossless current spreading, the emergent light of the chip is blue light, the arrangement period of the metal grating is 280 nm±30 nm, the width of the metal grating is 35 nm±5 nm, and the thickness of the metal grating is 40 nm±5 nm.

In the metal grating for lossless current spreading, the emergent light of the chip is blue light, the arrangement period of the metal grating is 100 nm±10 nm, the width of the metal grating is 14 nm±2 nm, and the thickness of the metal grating is 18 nm±2 nm.

In the metal grating for lossless current spreading, the emergent light of the chip is infrared light, the arrangement period of the metal grating is 500 nm±30 nm, the width of the metal grating is 60 nm±5 nm, and the thickness of the metal grating is 70 nm±5 nm.

In the metal grating for lossless current spreading, the emergent light of the chip is infrared light, the arrangement period of the metal grating is 180 nm±10 nm, the width of the metal grating is 25 nm±2 nm, and the thickness of the metal grating is 30 nm±2 nm.

In the metal grating for lossless current spreading, an adhesion layer is provided between the metal grating and the light-emitting surface of the chip, the metal grating is connected to the light-emitting surface of the chip through the adhesion layer, and the adhesion layer has a thickness of 5 nm±1 nm and a width that is the same as the width of the metal grating.

A method for manufacturing the metal grating for lossless current spreading, including specific steps as follows:
step 1: preprocessing of a chip:
   performing cleaning and a drying process on a light-emitting surface of the chip;
step 2: manufacturing of an adhesion layer:
   forming the adhesion layer on the light-emitting surface of the chip, where a thickness of the adhesion layer is 5 nm±1 nm;
step 3: patterning of a metal grating:
   manufacturing a photoresist pattern matching a size of a target metal grating on a surface of the adhesion layer;
step 4: manufacturing of the metal grating:
   forming the metal grating in a reserved area of the photoresist pattern, where a thickness of the metal grating ranges from 100-300% of a skin depth of a metal material corresponding to the metal grating; and
step 5: post-processing: removing remaining photoresist.

A method for manufacturing the metal grating for lossless current spreading, including specific steps as follows:
step 1: preprocessing of a chip:
   performing cleaning and a dry process on a light-emitting surface of the chip to remove impurities and an oxide layer on the surface;
step 2: formation of a groove:
   forming, on the light-emitting surface of the chip, the groove matching an arrangement period and a size of a target metal grating;
step 3: formation of an adhesion layer: forming the adhesion layer in the groove, where a thickness of the adhesion layer is 5 nm±1 nm;
step 4: patterning of a metal grating:
   manufacturing a photoresist pattern matching a size of a target metal grating on a surface of the adhesion layer;
step 5: manufacturing of the metal grating:
   forming the metal grating in a reserved area of the photoresist pattern, where a thickness of the metal grating ranges from 100-300% of a skin depth of a metal material corresponding to the metal grating; and
step 6: post-processing: removing remaining photoresist.

In the manufacturing method for the metal grating for lossless current spreading, in step 1, the cleaning is ultrasonic cleaning performed by using acetone, ethanol, and deionized water in sequence, with each ultrasonic cleaning time ranging from 10-15 min, a drying temperature ranging from 110-130 °C, and a drying time ranging from 20-40 min.

An LED chip includes the foregoing metal grating for lossless current spreading.

An LED chip includes a chip and a metal grating at a surface of the chip that is manufactured by using the manufacturing method for the metal grating for lossless current spreading described above.

Compared with the existing technology, the present invention has the following beneficial effects:
1. No loss of emergent light (an extremely low occlusion rate): In the present invention, the arrangement period of the metal grating for current spreading is designed in a subwavelength range of the emergent light, and the width is controlled to approximately ⅛ of the sub wavelength. In addition, a design is used where the thickness is 2 times the skin depth of the metal. An optical feature of a subwavelength structure is used to maximally reduce occlusion of emergent light from an epitaxial layer of a chip (a light-emitting surface of the chip) by the metal grating, so that the emergent light has no significant loss to greatly improve light efficiency of an LED chip. The present invention is especially applicable to a supplementary lighting scenario for plants having a severe requirement for light efficiency.
2. Excellent current spreading uniformity: The size, the arrangement period, and the thickness of the metal grating are accurately controlled to resolve a problem that a current distribution among conventional current spreading metal lines is uneven, so that current can be uniformly spread on a surface of a chip, avoiding problems such as heat generation of a chip and accelerated light decay caused by excessive concentration of local current and improving operation stability and a service life of a chip.
3. Reduction in a volume resistivity on a surface of a chip: Au is used as a material for the metal grating. The Au has excellent electrical conduction. In combination with a proper thickness design (2 times the skin depth), the volume resistivity on the surface of the chip is effectively reduced, energy loss in a current transmission process is reduced, and electro-optical transfer efficiency of a chip is further improved.
4. High binding strength and good stability: The nanoscale Ti adhesion layer is arranged between the metal grating and the epitaxial layer of the chip to effectively improve the binding strength between the metal grating and the surface of the chip and avoid falling and peeling of the metal grating. In addition, the Ti adhesion layer does not affect optical performance and electrical performance of the chip, thereby ensuring long-term stable operation of the chip.
5. Wide application range: The present invention has a main objective of improving light efficiency of a chip for supplementary lighting for plants and designing precise parameter solutions for red, blue, or infrared light chip for plants. In addition, the technical principle thereof may extend to various other types of LED chips and are not limited by a wavelength or a purpose of a chip, having a wide application prospect.
6. Manufacturing process which is practical and easy for industrialization: Processes, such as electron beam lithography, electron beam evaporation, spattering, and wet photoresist stripping, that are used in the present invention are all existing mature manufacturing processes for an LED chip. No new complex manufacturing equipment is needed and process parameters are easily controlled, so that scale-up production may be implemented with reduced production costs.

### BRIEF DESCRIPTION OF THE DRAWINGS

FIG. 1 is a distribution diagram of a metal grating and a bonding layer when the metal grating is higher than a surface of a chip.

FIG. 2 is a distribution diagram of a metal grating and a bonding layer when the metal grating is embedded into a surface of a chip.

### DETAILED DESCRIPTION

Technical solutions in embodiments of the present invention are clearly and completely described below with reference to accompanying drawings in embodiments of the present invention. Apparently, the described embodiments are merely some rather than all of embodiments of the present invention.

### Embodiment 1

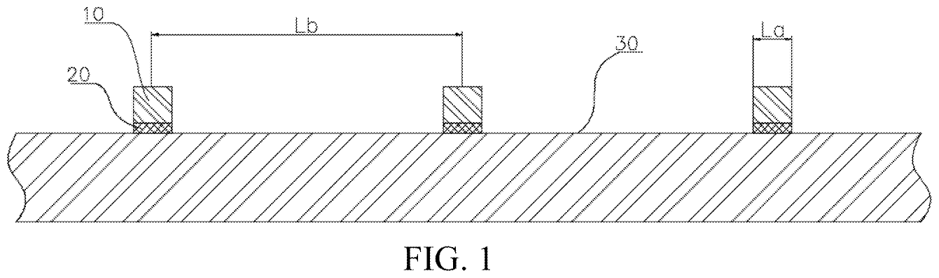

As shown in FIG. 1, this embodiment is a manufacturing method for manufacturing a metal grating for lossless current spreading of a red-light LED chip for plants, in which an emergent light wavelength is 670 nm and a metal grating 10 is higher than a surface of the chip. Specific steps are as follows:
1. Preprocessing of a chip:

A red-light LED chip for plants is selected, whose emergent light has a wavelength of 670 nm. Ultrasonic cleaning is performed on a light-emitting surface 30 of the chip (an exposed surface of an epitaxial layer of the chip) by using acetone, ethanol, and deionized water in sequence. Each ultrasonic cleaning time is 10 min. After the cleaning is completed, the chip is dried for 30 min by being placed in an oven at 120 °C to remove impurities and an oxide layer on the surface.
2. Manufacturing an adhesion layer 20:

An electron beam evaporation process is used. An adhesion layer 20 made of a Ti material is deposited on the light-emitting surface 30 of the chip (the exposed surface of the epitaxial layer of the chip), an evaporation rate is controlled to 0.1 nm/s, a vacuum degree is controlled to 5×10⁻⁵ Pa, and a deposition thickness is controlled to 5 nm. The adhesion layer 20 is ensured to be uniform and dense.
3. Patterning of a metal grating 10:

An electron beam lithography technology is used, and a photoresist is applied to a surface of an adhesion layer 20. After exposure and development, a photoresist line pattern with an arrangement period of 400 nm and a width of 50 nm is obtained.
4. Manufacturing of the metal grating 10:

An electron beam evaporation process is used, an Au layer is deposited on a preserved area of a photoresist pattern to obtain a metal grating 10, an evaporation rate is controlled to 0.2 nm/s, a vacuum degree is controlled to 5×10⁻⁵ Pa, and a deposition thickness is controlled to 60 nm, to ensure that the Au layer and the adhesion layer 20 made of a Ti material correspond to each other in position and are tightly bonded.
5. Post-process:

The chip is placed in an acetone solution, and ultrasonic photoresist removal is performed for 15 min to remove the remaining photoresist on the surface to obtain a shaped metal grating 10. Subsequently, the chip is placed in an annealing oven at 400 °C, and the annealing is performed for 30 min, to improve the binding strength.
6. Inspection and encapsulation:

The chip is inspected for parameters, such as current spreading uniformity, an occlusion rate of emergent light, and a volume resistivity, to confirm that the metal grating 10 has the arrangement period of Lb=400 nm with an allowed deviation of ±5 nm, a width of La=50 nm with an allowed deviation of ±3 nm, a thickness of 60 nm with an allowed deviation of ±3 nm, an occlusion rate less than 1%, a current of a spreading grating of 100%, a current of an uncovered grating region greater than 60%, and a current spreading uniformity error less 5%. After the requirement is satisfied, conventional encapsulation is performed to obtain a finished product.

### Embodiment 2

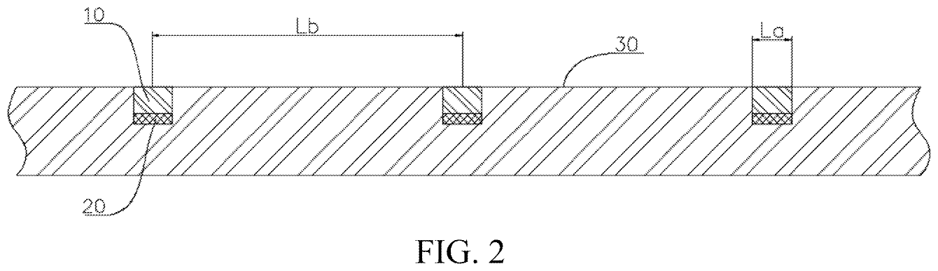

As shown in FIG. 2, this embodiment is a manufacturing method for manufacturing a metal grating for lossless current spreading of a red-light LED chip for plants, in which an emergent light wavelength is 670 nm and a metal grating 10 is higher than a surface of the chip. Specific steps are as follows:
1. Preprocessing of a chip:

A red-light LED chip for plants is selected, whose emergent light has a wavelength of 670 nm. Ultrasonic cleaning is performed on a light-emitting surface 30 of the chip (an exposed surface of an epitaxial layer of the chip) by using acetone, ethanol, and deionized water in sequence. Each ultrasonic cleaning time is 10 min. The chip is dried for 30 min in an oven at 120 °C.
2. Formation of a groove:

A plasma etching process is used. A groove having an arrangement period of 160 nm, a width of 20 nm, and a depth of 30 nm is formed on a light-emitting surface 30 of the chip (an exposed surface of an epitaxial layer of the chip) through etching. After the etching, the chip is cleaned and dried again.
3. Manufacturing an adhesion layer 20:

A spattering process is used. An adhesion layer 20 made of a Ti material is deposited in the groove. A spattering power is controlled to 100 W, a vacuum degree is controlled to 3×10⁻⁵ Pa, and a deposition thickness is controlled to 5 nm. The adhesion layer 20 is ensured to uniformly cover the groove.
4. Patterning of a metal grating 10:

An electron beam lithography technology is used. A photoresist pattern matching the size of the groove is manufactured on the surface of the adhesion layer 20 to ensure that the photoresist pattern is precisely aligned with the groove.
5. Manufacture a metal grating 10:

An electron beam evaporation process is used. An Au layer is deposited on the adhesion layer 20 and a preserved area for the photoresist, an evaporation rate is controlled to 0.2 nm/s, a vacuum degree is controlled to 5×10⁻⁵ Pa, and the deposition is performed until the Au layer is filled into the groove and flush with the light-emitting surface 30 of the chip.
6. Post-process:

Ultrasonic photoresist removal is performed using acetone for 15 min to remove the remaining photoresist to obtain a shaped metal grating 10. Then, the chip is placed in an annealing oven at 400 °C for annealing for 30 min to improve a binding strength.
7. Inspection and encapsulation: Inspection is made to confirm that the metal grating 10 has the arrangement period of Lb=160 nm with an allowed deviation of ±4 nm, a width of La=20 nm with an allowed deviation of ±2 nm, a thickness of 25 nm with an allowed deviation of ±2 nm, an occlusion rate less than 2%, a current of a spreading grating of 100%, a current of an uncovered grating region greater than 60%, and a current spreading uniformity error less 5%. After the requirement is satisfied, encapsulation is performed to obtain a finished product.

### Embodiment 3

As shown in FIG. 1, this embodiment is a manufacturing method for manufacturing a metal grating for lossless current spreading of a blue-light LED chip for plants, in which an emergent light wavelength is 450 nm and a metal grating 10 is flush with a surface of the chip. Specific steps are as follows:
1. Preprocessing of a chip:

A blue-light LED chip for plants is selected, whose emergent light has a wavelength of 450 nm. Ultrasonic cleaning is performed on a light-emitting surface 30 of the chip (an exposed surface of an epitaxial layer of the chip) by using acetone, ethanol, and deionized water in sequence. Each ultrasonic cleaning time is 10 min. After the cleaning is completed, the chip is dried for 30 min by being placed in an oven at 120 °C to remove impurities and an oxide layer on the surface.
2. Manufacturing an adhesion layer 20:

An electron beam evaporation process is used. An adhesion layer 20 made of a Ti material is deposited on the light-emitting surface 30 of the chip (the exposed surface of the epitaxial layer of the chip), an evaporation rate is controlled to 0.1 nm/s, a vacuum degree is controlled to 5×10⁻⁵ Pa, and a deposition thickness is controlled to 5 nm. The adhesion layer 20 is ensured to be uniform and dense.
3. Patterning of a metal grating 10:

An electron beam lithography technology is used, and a photoresist is applied to a surface of an adhesion layer 20. After exposure and development, a photoresist line pattern with an arrangement period of 280 nm and a width of 35 nm is obtained.
4. Manufacturing of the metal grating 10:

An electron beam evaporation process is used, an Au layer is deposited on a preserved area of a photoresist pattern to obtain a metal grating 10, an evaporation rate is controlled to 0.2 nm/s, a vacuum degree is controlled to 5×10⁻⁵ Pa, and a deposition thickness is controlled to 40 nm, to ensure that the Au layer and the adhesion layer 20 made of a Ti material correspond to each other in position and are tightly bonded.
5. Post-process:

The chip is placed in an acetone solution, and ultrasonic photoresist removal is performed for 15 min to remove the remaining photoresist on the surface to obtain a shaped metal grating 10. Subsequently, the chip is placed in an annealing oven at 400 °C, and the annealing is performed for 30 min, to improve the binding strength.
6. Inspection and Encapsulation:

The chip is inspected for parameters, such as current spreading uniformity, an occlusion rate of emergent light, and a volume resistivity, to confirm that the metal grating 10 has the arrangement period of Lb=280 nm with an allowed deviation of ±5 nm, a width of La=35 nm with an allowed deviation of ±3 nm, a thickness of 40 nm with an allowed deviation of ±3 nm, an occlusion rate less than 1%, a current of a spreading grating of 100%, a current of an uncovered grating region greater than 60%, and a current spreading uniformity error less 5%. After the requirement is satisfied, conventional encapsulation is performed to obtain a finished product.

### Embodiment 4

As shown in FIG. 2, this embodiment is a manufacturing method for manufacturing a metal grating for lossless current spreading of a blue-light LED chip for plants, in which an emergent light wavelength is 450 nm and a metal grating 10 is flush with a surface of the chip. Specific steps are as follows:
1. Preprocessing of a chip:

A blue-light LED chip for plants is selected, whose emergent light has a wavelength of 450 nm. Ultrasonic cleaning is performed on a light-emitting surface 30 of the chip (an exposed surface of an epitaxial layer of the chip) by using acetone, ethanol, and deionized water in sequence. Each ultrasonic cleaning time is 10 min. The chip is dried for 30 min in an oven at 120 °C.
2. Formation of a groove:

A plasma etching process is used. A groove having an arrangement period of 100 nm, a width of 14 nm, and a depth of 23 nm is formed on a light-emitting surface 30 of the chip (an exposed surface of an epitaxial layer of the chip) through etching. After the etching, the chip is cleaned and dried again.
3. Formation of an adhesion layer 20:

A spattering process is used. An adhesion layer 20 made of a Ti material is deposited in the groove. A spattering power is controlled to 100 W, a vacuum degree is controlled to 3×10⁻⁵ Pa, and a deposition thickness is controlled to 5 nm. The adhesion layer 20 is ensured to uniformly cover the groove.
4. Patterning preparation of a metal grating 10:

An electron beam lithography technology is used. A photoresist pattern matching the size of the groove is manufactured on the surface of the adhesion layer 20 to ensure that the photoresist pattern is precisely aligned with the groove.
5. Depositing of the metal grating 10:

An electron beam evaporation process is used. An Au layer is deposited on the adhesion layer 20 and a preserved area for the photoresist, an evaporation rate is controlled to 0.2 nm/s, a vacuum degree is controlled to 5×10⁻⁵ Pa, and a deposition thickness is 18 nm to ensure that the Au layer is filled into the groove and flush with the light-emitting surface 30 of the chip.
6. Post-process:

Ultrasonic photoresist removal is performed using acetone for 15 min to remove the remaining photoresist to obtain a shaped metal grating 10. Then, the chip is placed in an annealing oven at 400 °C for annealing for 30 min to improve a binding strength.
7. Inspection and encapsulation: Inspection is made to confirm that the metal grating 10 has the arrangement period of Lb=100 nm with an allowed deviation of ±4 nm, a width of La=14 nm with an allowed deviation of ±2 nm, a thickness of 18 nm with an allowed deviation of ±2 nm, an occlusion rate less than 2%, a current of a spreading grating of 100%, a current of an uncovered grating region greater than 60%, and a current spreading uniformity error less 5%. After the requirement is satisfied, encapsulation is performed to obtain a finished product.

### Embodiment 5

As shown in FIG. 1, this embodiment is a manufacturing method for manufacturing a metal grating for lossless current spreading of an infrared-light LED chip for plants, in which an emergent light wavelength is 730 nm and a metal grating 10 is higher than a surface of the chip. Specific steps are as follows:
1. Preprocessing of a chip:

An infrared-light LED chip for plants is selected, whose emergent light has a wavelength of 730 nm. Ultrasonic cleaning is performed on a light-emitting surface 30 of the chip (an exposed surface of an epitaxial layer of the chip) by using acetone, ethanol, and deionized water in sequence. Each ultrasonic cleaning time is 10 min. After the cleaning is completed, the chip is dried for 30 min by being placed in an oven at 120 °C to remove impurities and an oxide layer on the surface.
2. Manufacturing an adhesion layer 20:

An electron beam evaporation process is used. An adhesion layer 20 made of a Ti material is deposited on the light-emitting surface 30 of the chip (the exposed surface of the epitaxial layer of the chip), an evaporation rate is controlled to 0.1 nm/s, a vacuum degree is controlled to 5×10⁻⁵ Pa, and a deposition thickness is controlled to 5 nm. The adhesion layer 20 is ensured to be uniform and dense.
3. Patterning of a metal grating 10:

An electron beam lithography technology is used, and a photoresist is applied to a surface of an adhesion layer 20. After exposure and development, a photoresist line pattern with an arrangement period of 500 nm and a width of 60 nm is obtained.
4. Manufacturing of the metal grating 10:

An electron beam evaporation process is used, an Au layer is deposited on a preserved area of a photoresist pattern to obtain a metal grating 10, an evaporation rate is controlled to 0.2 nm/s, a vacuum degree is controlled to 5×10⁻⁵ Pa, and a deposition thickness is controlled to 70 nm, to ensure that the Au layer and the adhesion layer 20 made of a Ti material correspond to each other in position and are tightly bonded.
5. Post-process:

The chip is placed in an acetone solution, and ultrasonic photoresist removal is performed for 15 min to remove the remaining photoresist on the surface to obtain a shaped metal grating 10. Subsequently, the chip is placed in an annealing oven at 400 °C, and the annealing is performed for 30 min, to improve the binding strength.
6. Inspection and encapsulation:

The chip is inspected for parameters, such as current spreading uniformity, an occlusion rate of emergent light, and a volume resistivity, to confirm that the metal grating 10 has the arrangement period of Lb=500 nm with an allowed error of ±5 nm, a width of La=60 nm with an allowed error of ±3 nm, a thickness of 70 nm with an allowed error of ±3 nm, an occlusion rate less than 1%, a current of a spreading grating of 100%, a current of an uncovered grating region greater than 60%, and a current spreading uniformity error less 5%. After the requirement is satisfied, conventional encapsulation is performed to obtain a finished product.

### Embodiment 6

As shown in FIG. 2, this embodiment is a manufacturing method for manufacturing a metal grating for lossless current spreading of an infrared-light LED chip for plants, in which an emergent light wavelength is 730 nm and a metal grating 10 is higher than a surface of the chip. Specific steps are as follows:
1. Preprocessing of a chip:

An infrared-light LED chip for plants is selected, whose emergent light has a wavelength of 730 nm. Ultrasonic cleaning is performed on a light-emitting surface 30 of the chip (an exposed surface of an epitaxial layer of the chip) by using acetone, ethanol, and deionized water in sequence. Each ultrasonic cleaning time is 10 min. The chip is dried for 30 min in an oven at 120 °C.
2. Formation of a groove:

A plasma etching process is used. A groove having an arrangement period of 180 nm, a width of 25 nm, and a depth of 35 nm is formed on a light-emitting surface 30 of the chip (an exposed surface of an epitaxial layer of the chip) through etching. After the etching, the chip is cleaned and dried again.
3. Formation of an adhesion layer 20:

A spattering process is used. An adhesion layer 20 made of a Ti material is deposited in the groove. A spattering power is controlled to 100 W, a vacuum degree is controlled to 3×10⁻⁵ Pa, and a deposition thickness is controlled to 5 nm. The adhesion layer 20 is ensured to uniformly cover the groove.
4. Patterning preparation of a metal grating 10:

An electron beam lithography technology is used. A photoresist pattern matching the size of the groove is manufactured on the surface of the adhesion layer 20 to ensure that the photoresist pattern is precisely aligned with the groove.
5. Depositing of the metal grating 10:

An electron beam evaporation process is used. An Au layer is deposited on the adhesion layer 20 and a preserved area for the photoresist, an evaporation rate is controlled to 0.2 nm/s, a vacuum degree is controlled to 5×10⁻⁵ Pa, and a deposition thickness is 30 nm to ensure that the Au layer is filled into the groove and flush with the light-emitting surface 30 of the chip.
6. Post-process:

Ultrasonic photoresist removal is performed using acetone for 15 min to remove the remaining photoresist to obtain a shaped metal grating 10. Then, annealing is performed at 400 °C for 30 min to improve a binding strength.
7. Inspection and encapsulation: Inspection is made to confirm that the metal grating 10 has the arrangement period of Lb=180 nm with an allowed deviation of ±4 nm, a width of La=25 nm with an allowed deviation of ±2 nm, a thickness of 30 nm with an allowed deviation of ±2 nm, an occlusion rate less than 2%, a current of a spreading grating of 100%, a current of an uncovered grating region greater than 60%, and a current spreading uniformity error less 5%. After the requirement is satisfied, encapsulation is performed to obtain a finished product.

### Embodiment 7

An LED chip is manufactured by using the method in Embodiment 1, and the LED chip is a red-light LED chip for plants.

### Embodiment 8

An LED chip is manufactured by using the method in Embodiment 2, and the LED chip is a red-light LED chip for plants.

### Embodiment 9

An LED chip is manufactured by using the method in Embodiment 3, and the LED chip is a blue-light LED chip for plants.

### Embodiment 10

An LED chip is manufactured by using the method in Embodiment 4, and the LED chip is a blue-light LED chip for plants.

### Embodiment 11

An LED chip is manufactured by using the method in Embodiment 5, and the LED chip is an infrared-light LED chip for plants.

### Embodiment 12

An LED chip is manufactured by using the method in Embodiment 6, and the LED chip is an infrared-light LED chip for plants.

What is claimed is:

1. A metal grating for lossless current spreading, wherein the metal grating (10) is disposed at a light-emitting surface (30) of a chip;
an arrangement period of the metal grating (10) is at a subwavelength scale of emergent light from the chip; and
a width of the metal grating (10) ranges from 1/9 to 1/7 of the arrangement period, and a thickness of the metal grating ranges from 100-300% of a skin depth of a material of the metal grating (10).

2. The metal grating for lossless current spreading according to claim 1, wherein the width of the metal grating (10) is ⅛ of the arrangement period, and the thickness of the metal grating (10) ranges from 150-250% of the skin depth of the material of the metal grating (10).

3. The metal grating for lossless current spreading according to claim 1, wherein the metal grating (10) is higher than the light-emitting surface (30) of the chip, and a wavelength of the emergent light is a wavelength of the emergent light in air.

4. The metal grating for lossless current spreading according to claim 1, wherein the metal grating (10) is embedded in a surface of the chip, a top of the metal grating is flush with the light-emitting surface (30) of the chip, and the wavelength of the emergent light is an internal wavelength of the emergent light on the light-emitting surface (30) of the chip.

5. The metal grating for lossless current spreading according to claim 3, wherein the emergent light of the chip is red light, the arrangement period of the metal grating (10) is 400 nm±40 nm, the width of the metal grating (10) is 50 nm±5 nm, and the thickness of the metal grating is 60 nm±6 nm.

6. The metal grating for lossless current spreading according to claim 4, wherein the emergent light of the chip is red light, the arrangement period of the metal grating (10) is 160 nm±15 nm, the width of the metal grating (10) is 20 nm±3 nm, and the thickness of the metal grating is 25 nm±3 nm.

7. The metal grating for lossless current spreading according to claim 3, wherein the emergent light of the chip is blue light, the arrangement period of the metal grating (10) is 280 nm±30 nm, the width of the metal grating (10) is 35 nm±5 nm, and the thickness of the metal grating is 40 nm±5 nm.

8. The metal grating for lossless current spreading according to claim 4, wherein the emergent light of the chip is blue light, the arrangement period of the metal grating (10) is 100 nm±10 nm, the width of the metal grating (10) is 14 nm±2 nm, and the thickness of the metal grating is 18 nm±2 nm.

9. The metal grating for lossless current spreading according to claim 3, wherein the emergent light of the chip is infrared light, the arrangement period of the metal grating (10) is 500 nm±30 nm, the width of the metal grating (10) is 60 nm±5 nm, and the thickness of the metal grating is 70 nm ±5 nm.

10. The metal grating for lossless current spreading according to claim 4, wherein the emergent light of the chip is infrared light, the arrangement period of the metal grating (10) is 180 nm±10 nm, the width of the metal grating is 25 nm±2 nm, and the thickness of the metal grating is 30 nm±2 nm.

11. The metal grating for lossless current spreading according to claim 1, wherein an adhesion layer (20) is provided between the metal grating (10) and the light-emitting surface (30) of the chip, the metal grating (10) is connected to the light-emitting surface (30) of the chip through the adhesion layer, and the adhesion layer (20) has a thickness of 5 nm±1 nm and a width that is the same as the width of the metal grating (10).

12. The metal grating for lossless current spreading according to claim 2, wherein an adhesion layer (20) is provided between the metal grating (10) and the light-emitting surface (30) of the chip, the metal grating (10) is connected to the light-emitting surface (30) of the chip through the adhesion layer, and the adhesion layer (20) has a thickness of 5 nm±1 nm and a width that is the same as the width of the metal grating (10).

13. The metal grating for lossless current spreading according to claim 3, wherein an adhesion layer (20) is provided between the metal grating (10) and the light-emitting surface (30) of the chip, the metal grating (10) is connected to the light-emitting surface (30) of the chip through the adhesion layer, and the adhesion layer (20) has a thickness of 5 nm±1 nm and a width that is the same as the width of the metal grating (10).

14. The metal grating for lossless current spreading according to claim 4, wherein an adhesion layer (20) is provided between the metal grating (10) and the light-emitting surface (30) of the chip, the metal grating (10) is connected to the light-emitting surface (30) of the chip through the adhesion layer, and the adhesion layer (20) has a thickness of 5 nm±1 nm and a width that is the same as the width of the metal grating (10).

15. A manufacturing method for the metal grating for lossless current spreading according to claim 3, wherein specific steps are as follows:
step 1: preprocessing of a chip:
performing cleaning and a drying process on a light-emitting surface (30) of the chip;
step 2: manufacturing of an adhesion layer (20):
forming the adhesion layer (20) on the light-emitting surface (30) of the chip, wherein a thickness of the adhesion layer (20) is 5 nm±1 nm;
step 3: patterning of a metal grating (10):
manufacturing a photoresist pattern matching a size of a target metal grating (10) on a surface of the adhesion layer (20);
step 4: manufacturing of the metal grating (10):
forming the metal grating (10) in a reserved area of the photoresist pattern, wherein a thickness of the metal grating (10) ranges from 100-300% of a skin depth of a metal material corresponding to the metal grating (10); and
step 5: post-processing: removing remaining photoresist.

16. A manufacturing method for the metal grating for lossless current spreading according to claim 4, wherein specific steps are as follows:
step 1: preprocessing of a chip:
performing cleaning and a drying process on a light-emitting surface (30) of the chip;
step 2: formation of a groove:
forming, on the light-emitting surface (30) of the chip, the groove matching an arrangement period and a size of a target metal grating (10);
step 3: formation of an adhesion layer (20):
forming the adhesion layer (20) in the groove, wherein a thickness of the adhesion layer (20) is 5 nm ±1 nm;
step 4: patterning of a metal grating (10):
manufacturing a photoresist pattern matching a size of a target metal grating (10) on a surface of the adhesion layer (20);
step 5: manufacturing of the metal grating (10):
forming the metal grating (10) in a reserved area of the photoresist pattern, wherein a thickness of the metal grating (10) ranges from 100-300% of a skin depth of a metal material corresponding to the metal grating (10); and
step 6: post-processing: removing remaining photoresist.

17. The manufacturing method for the metal grating for lossless current spreading according to claim 15, wherein in step 1, the cleaning is ultrasonic cleaning performed by using acetone, ethanol, and deionized water in sequence, with each ultrasonic cleaning time ranging from 10-15 min, a drying temperature ranging from 110-130°C, and a drying time ranging from 20-40 min.

18. The manufacturing method for the metal grating for lossless current spreading according to claim 16, wherein in step 1, the cleaning is ultrasonic cleaning performed by using acetone, ethanol, and deionized water in sequence, with each ultrasonic cleaning time ranging from 10-15 min, a drying temperature ranging from 110-130°C, and a drying time ranging from 20-40 min.

19. An LED chip, comprising the metal grating for lossless current spreading according to claim 1.
